(19) United States
(12) Patent Application Publication
(10) Pub. No.: US 2004/0013003 A1
(43) Pub. Date: Jan. 22, 2004

(54) First bit data eye compensation for open drain output driver

(75) Inventor: Brian W. Huber, Allen, TX (US)

Correspondence Address: Hugh R. Kress, WINSTEAD SECHREST & MINICK P.C., 910 Travis Street, Houston, TX, 77002, US

(73) Assignee: Micron Technology, Inc., Boise, ID

(21) Appl. No.: 10/199,410

(22) Filed: Jul. 19, 2002

(51) Int. Cl. G11C 5/00

(52) U.S. Cl. 365/189.05

(57) ABSTRACT

An open-drain output circuit for a semiconductor device is provided with a mechanism for compensating for variations in the length of time that the driver circuit presents valid data at an output terminal of a semiconductor device. In one embodiment, the valid data “data eye” for the driver circuit is reduced for the first bit following extended turn-off of the driver circuit as compared with the valid data eye for subsequent bits, a “first bit data eye phenomenon.” To compensate for the first bit data eye phenomenon, circuitry is provided for causing the driver circuit to turn on earlier when the driver circuit has previously been off for relative to when the driver circuit has not been off for. In one embodiment, the compensation circuitry comprises circuitry for assessing the voltage level present on a specified node in the driver circuit, where that voltage level is indicative of the length of time that the driver circuit has been turned off. The voltage level is fed back to a pre-driver circuit which provides a pre-driver output signal to the output circuit in response to data read input signals. In one embodiment, the pre-driver circuit asserts its output after a delay interval following assertion of the data read input signal, and the length of that delay interval is determined by the voltage level on the specified node in the driver circuit.

### FIELD OF THE INVENTION

This invention relates generally to semiconductor devices, and more particularly relates to an open-drain output circuit for a semiconductor device.

### BACKGROUND OF THE INVENTION

Integrated circuits typically include a number of input/output pins which are used for communication with additional circuitry. For example, an integrated memory device such as a dynamic random access memory (DRAM) includes both control inputs for receiving memory operation control signals, and data pins for bi-directional data communication with an external system or processor.

The data transmission rate of modern integrated circuits is primarily limited by internal circuitry operating speeds. That is, communication networks have been developed which can transmit signals between circuitry at a rate that is faster than the capacity of many integrated circuits. To address the need for faster circuits, a group of integrated circuits can be combined on a common bus. In this configuration, each integrated circuit operates in a coordinated manner with the other integrated circuits to share data which is transmitted at a high speed. For example, a group of memory devices, such as DRAMs, static RAMs, or read only memories (ROM), can be connected to a common data bus. The data rate of the bus may be substantially faster than the feasible operating speed of the individual memories. Each memory, therefore, is operated so that while one memory is processing received data, another memory is receiving new data. By providing an appropriate number of memory devices and an efficient control system, very high speed data transmissions can be achieved.

As the transmission rate of the data communication signals continues to increase, new circuitry and methods are needed to accurately transmit data from each integrated circuit. One proposed solution is a bus driver described in U.S. Pat. No. 5,254,883. This bus driver circuit uses parallel open-drain output transistors. The output transistors are fabricated in different sizes and selectively activated to control the bus current. This technique requires a relatively large number of output transistors to implement.

In one type of open-drain output circuit, a substantially constant reference voltage is applied to the gate of the open-drain output transistor, as will be discussed hereinbelow with reference to FIG. 2. Those of ordinary skill in the art will appreciate that it is possible for various initial conditions on middle node 42 during operation to adversely affect the uniformity of output transition characteristics appearing on the output pad driven by the output circuit gate. Such non-uniformity in the output transitions can reduce the maximum usable frequency at which the circuit may operate.

The period in which data presented on an output pad of a memory device is valid during a given clock cycle portion is often referred to as the “data eye” or data envelope. Those of ordinary skill in the art will appreciate that although signal transitions representing a succession of data bits presented on an output terminal would ideally occur instantaneously (i.e., with true, square rising and falling edges), in practical implementations, such transitions are more gradual. That is, a signal's transition from a logic high level to a logic low level takes some amount of time. This means that, for a given clock cycle portion, the period during which the data is valid for a given output bit—the data eye—is something less than the entire duration of the clock cycle for single data rate transmissions or something less than a half cycle clock for a double data rate transmission.

The difference between the length of a clock cycle and the data eye in which valid data is available on an output pad of a memory device is illustrated in FIG. 1. Waveform 10 in FIG. 1 represents an idealized clock signal (CLK) having true, square rising (12) and falling (14, 16) edges. CLK signal 10 may be, for example, a 400 MHz system clock, with a full clock cycle (i.e., from rising edge to rising edge or falling edge to falling edge) of approximately 2.5 nsec. Waveforms designated collectively with reference numeral 18 in FIG. 1 represent data signals present on a plurality of output pads of a hypothetical memory device. As is apparent from FIG. 1, the waveforms represented therein correspond to a double-data rate memory device, in which data is transferred on both the rising and falling edges of the system clock signal.

Reference numerals 20 in FIG. 1 identify so-called “data eyes” for the hypothetical memory device of FIG. 1. As shown in FIG. 1, a first data eye 20 extends from time t2 to time t3, and a second data eye 20 extends from time t5 to time t6. It is apparent from FIG. 1, therefore, that a data eye lasts for some period less than the clock cycle (or half cycle) in which it occurs. Whereas a first half cycle in FIG. 1, from falling edge 14 to rising edge 12 extends from time t1 to time t4, the corresponding data eye 20 extends only from time t2 to time t3, where (t4−t1)>(t3−t2).

In one common type of open-drain output circuit, a pair of series-connected transistors are disposed between the output pad and ground potential, and a constant termination voltage is applied to the pad. Those of ordinary skill in the art will recognize that there can be an increase in the voltage on the middle node between the two series-connected transistors, depending upon the length of time since the transistors were last operated to drive data on the output pad. Those of ordinary skill in the art will appreciate, as will be described hereinbelow in greater detail, that it is possible for this phenomenon to adversely effect the performance of the output circuit for an initial period of time (one or more bits) immediately after the output circuit is operated after being inactive for a sufficiently long time. In particular, the gradual increase in voltage on the middle node between the two series-connected output transistors can reduce the data eye for the first one or more bits outputted by the output circuit following long periods of inactivity.

Thus, it is believed that it would be desirable to provide an output circuit arrangement which the data eye is maximized, in order to ensure that data latching circuits in devices reading data out of a memory device have the maximum amount of time to operate on valid data. Further, it is believed that it would be desirable to compensate for the effects of voltage increases within the circuit occurring when the circuit is inactive for relatively long periods of time.

### SUMMARY OF THE INVENTION

In view of the foregoing and other considerations, the present invention relates to an apparatus and corresponding method for improving first bit data eye performance in an open-drain output circuit.

In one embodiment of the invention, a pre-driver circuit providing the input to an open-drain output driver circuit is operated to assert, after a delay interval, a pre-driver output signal in response assertion of a read data input signal applied to the pre-driver. In accordance with one aspect of the invention, the length of the delay interval between assertion of the read data input signal and assertion of the pre-driver output signal is determined in part by the length of time immediately prior to assertion of the read data signal that the output driver circuit has been turned off.

In another embodiment of the invention, circuitry is provided for detecting a voltage present on a middle node in the output driver circuit, and in response to the detected voltage, varying the delay between assertion of a read data input signal to the pre-driver circuit and assertion of the pre-driver output signal.

The circuitry for detecting a voltage present on the middle node of the output driver circuit in one embodiment comprises one or more transistors having a gate terminal coupled to the middle node. As the voltage on the middle node increases when the output driver circuit remains in an off state for an extended period of time, such transistor(s) is/are biased toward turn-on. The placement of these transistors in the circuit is such that when biased toward turn-on, the pre-driver circuit tends to drive its pre-driver output signal earlier.

### BRIEF DESCRIPTION OF THE DRAWINGS

The foregoing and other features and aspects of the present invention will be best understood with reference to the following detailed description of a specific embodiment of the invention, when read in conjunction with the accompanying drawings, wherein:

FIG. 1 is a plot showing a system clock and a plurality of data signals present on the output terminals of a memory device;

FIG. 2 is a simplified schematic diagram of a prior art open-drain output circuit;

FIG. 3 is a timing diagram showing the reduction in the data eye of the first bit driven following prolonged turn-off of the open driver circuit of FIG. 2;

FIG. 4 is a schematic diagram representing one method for compensating for first-bit data eye reduction in an open-drain output driver circuit;

FIG. 5 is a schematic diagram representing an alternative method for compensating for first-bit data eye reduction in an open-drain output driver circuit;

FIG. 6 is a simplified schematic diagram of an open-drain driver circuit and associated pre-driver circuit in accordance with one embodiment of the invention;

FIG. 7 is a more detailed schematic diagram of the open-drain driver circuit and associated pre-driver circuit from FIG. 6;

FIG. 8 is a simplified schematic diagram of a delay circuit for conditioning clock signals applied to the pre-driver circuit of FIG. 7;

FIG. 9 is a plot showing various voltages in the circuit of FIG. 7 during operation thereof;

FIG. 10 is a schematic diagram of an open-drain driver circuit and associated pre-driver circuit in accordance with an alternative embodiment of the invention; and

FIGS. 11a and 11b are schematic diagrams of decoding circuitry used to condition the state of nodes in the pre-driver circuit of FIG. 10.

### DETAILED DESCRIPTION OF SPECIFIC EMBODIMENTS OF THE INVENTION

In the disclosure that follows, in the interest of clarity, not all features of actual implementations are described. It will of course be appreciated that in the development of any such actual implementation, as in any such project, numerous engineering and programming decisions must be made to achieve the developers' specific goals and subgoals (e.g., compliance with system and technical constraints), which will vary from one implementation to another. Moreover, attention will necessarily be paid to proper engineering practices for the environment in question. It will be appreciated that such a development effort might be complex and time-consuming, but would nevertheless be a routine undertaking for those of ordinary skill in the relevant fields.

Furthermore, for the purposes of the present disclosure, the terms “comprise” and “comprising” shall be interpreted in an inclusive, non-limiting sense, recognizing that an element or method step said to “comprise” one or more specific components may include additional components. Also, it is to be understood that the terms “coupled” and “coupled to” as used to describe the interrelationship of two recited elements shall be interpreted so as to not exclude the possibility of intermediate elements disposed between the recited elements. That is, a first element may be “coupled to” a second element indirectly by means of one or more additional elements (for example (without limitation), a resistor, a transistor, or an inverter, and the terms “coupled” and “coupled to” shall necessarily not be interpreted as either implying or excluding being “coupled directly” or “coupled directly to.” Such a distinction is especially relevant in situations where a first element is “selectively” coupled to a second element, for example through the source-to-drain path of a transistor, or where a logic signal passes through an even number of inverters.

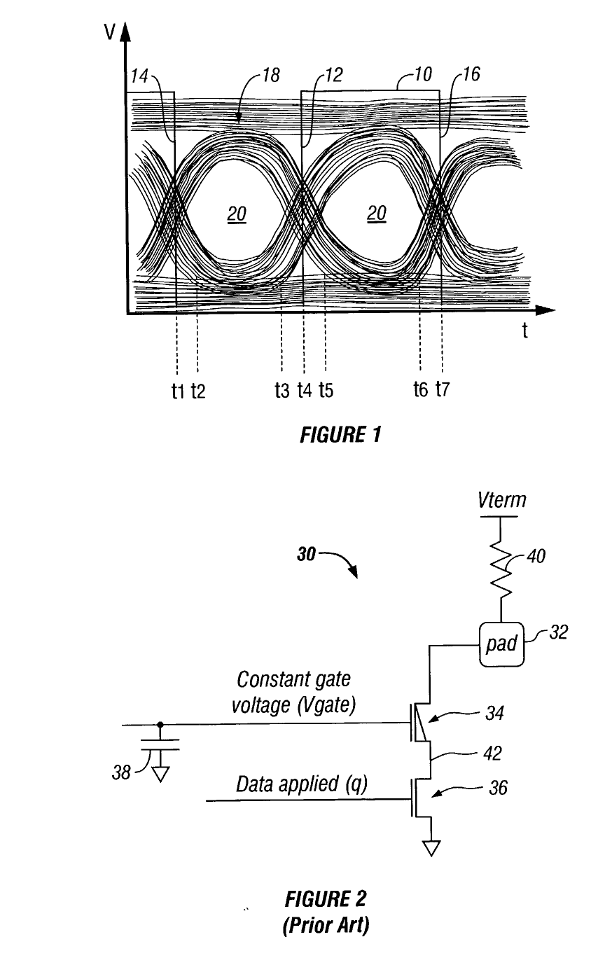

Referring to FIG. 2, there is shown a prior art open-drain output circuit 30 for driving an output signal on an output pad 32 of a semiconductor device. As shown in FIG. 2, output circuit 30 comprises an N-channel output field-effect transistor (FET) 34 and a second N-channel FET 36 coupled in series between output pad 32 and ground potential. A substantially constant gate potential V_{gate} is maintained on the gate of output transistor 34, and a capacitance 38 is coupled between the gate of transistor 34 and ground potential. Gate potential V_{gate} is preferably generated by a voltage regulator circuit (not shown in FIG. 1) in accordance with conventional practice in the art. The term “substantially constant” is used herein in recognition of the fact that depending upon the particular implementation of a voltage regulator circuit, the V_{gate} voltage may be susceptible to minor fluctuations due, for example, to capacitive coupling effects, noise, processing variation, and so on, as would be appreciated by those of ordinary skill in the art. Finally, output circuit 30 further comprises a termination resistance 40 coupled between output pad 32 and a termination voltage Vₜₑᵣₘ.

Operation of output circuit 30 occurs as follows: When input signal q is asserted to a logical high level, FET 36 turns on, providing a current path between an intermediate node (middle node) 42 and ground potential. Thus, a current path from Vₜₑᵣₘ to ground is established, and the voltage on output pad 32 is pulled towards ground. Specifically, in one embodiment, the on resistances of transistors 34 and 36 are tuned such that when acting on resistor 40, pad 32 pulls down to approximately 1.0 V (steady state case) whereas when transistor 36 is off, pad 32 reaches Vₜₑᵣₘ (e.g., 1.8 V). On the other hand, when input signal q is at a low logical level, FET 36 turns off, such that no current path is present through transistor 34. Under these circumstances, the voltage on output pad 32 is maintained at a positive voltage of Vₜₑᵣₘ less the voltage drop across resistor 40.

Middle node 42 between transistors 34 and 36 will be near ground potential when output circuit 30 is “on” (i.e., driving a low logic level on pad 32). When output circuit 30 is off (i.e., when input signal q is at a low logic level), the voltage level on middle node 42 is dependent upon the length of time that the output has been off. When the memory device is active, i.e., when output circuit 30 is turned on and off at normal operating speeds, the voltage level on middle node rise roughly 25% to 50% of the difference from the “on” case to the steady-state “off” case. However, when output circuit 30 remains off for an extended period of time, the voltage on middle node 42 will gradually rise above this early off level.

As the middle node voltage increases, transistor 34 begins to operate in the sub-threshold region resulting in logarithmic resistance variation versus the middle node voltage. For example, if the output circuit 30 has been off for 0.5 nSec, the voltage on middle node 42 may reach 0.4V. After 1 nSec, the middle node voltage may be slightly higher. After 1 Sec, the middle node can reach as high as 0.9V or so. These different voltage values impact how the output subsequently turns on, potentially resulting in varied edge timings and consequently reducing the output data eye for the first one or more bits after resumption of operation.

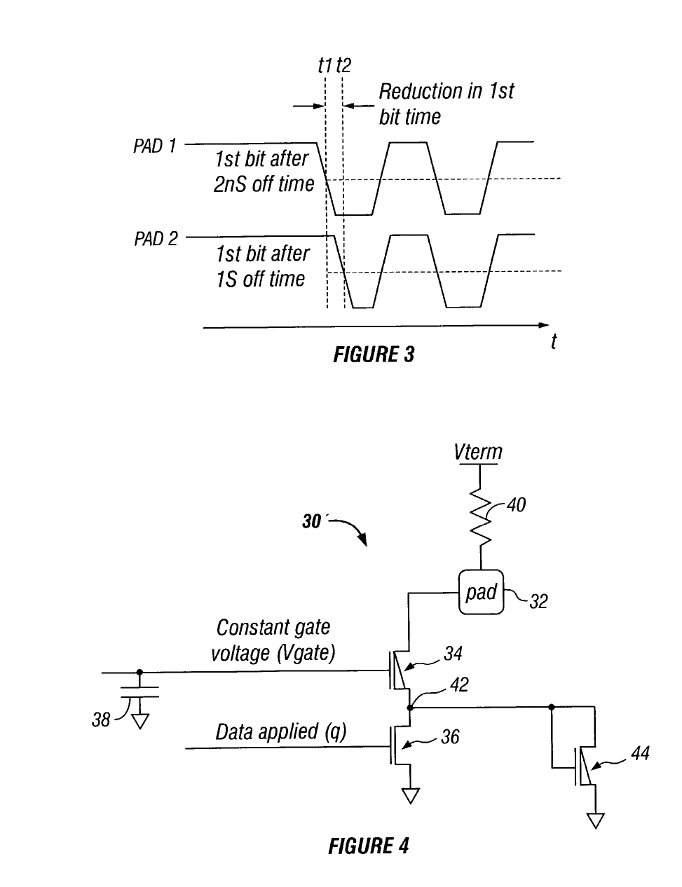

This “first bit data eye reduction” phenomenon is illustrated in FIG. 3. Waveform PAD1 in FIG. 3 represents a situation where output circuit 30 has been “off” (i.e., input q low) for only 2 nSec. As shown in FIG. 3 the data eye for the PAD1 signal (defined by where the signal crosses the mid-point between logic high and low levels) begins at time t1. On the other hand, waveform PAD2 in FIG. 3 corresponds to the situation in which output circuit 30 has been off for 1 Sec. In this case, the data eye for PAD2 begins at time t2, noticeably after time t1. This results in the reduction in data eye size for the first bit following turn-on.

One approach for reducing the voltage variation in the middle node 42 would be to clamp the middle node 42. As shown in FIG. 4, this can be achieved in output circuit 30′ with a diode-configured transistor 44. (In FIG. 4, elements that are identical to the output circuit of FIG. 2 retain identical reference numerals.) One drawback to this approach, however, is that it will draw some level of current when output circuit 30′ is off.

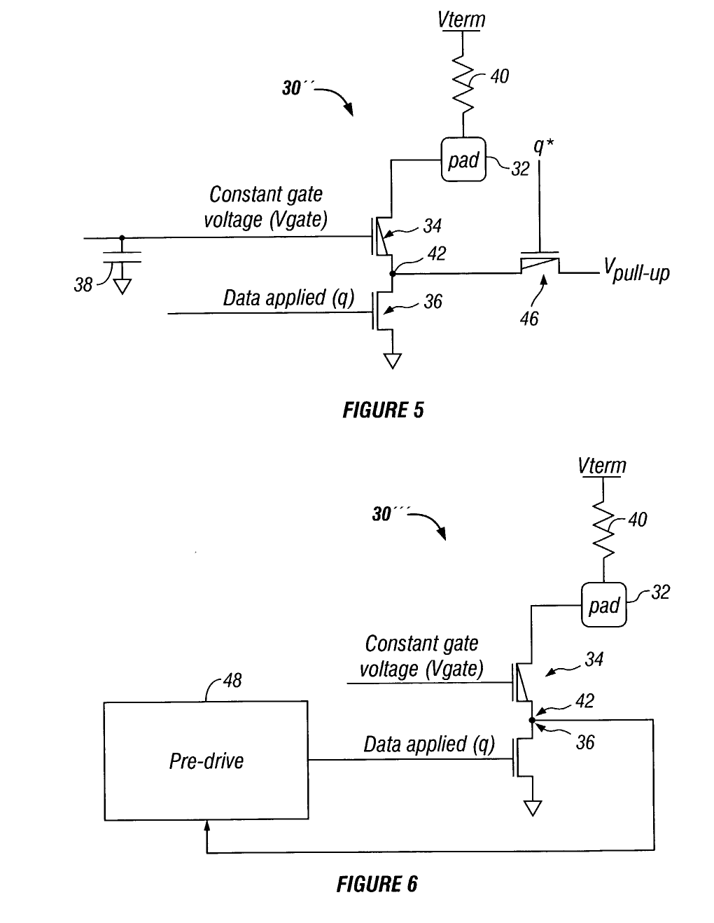

Another approach is to pull up the middle node 42 to a higher potential than the steady state value (i.e., greater than 0.9V) after every output turn-off. This could be implemented such that middle node 42 would reach this higher potential within one half clock cycle to ensure consistent middle node voltages regardless of off time. FIG. 5 shows one example of such an approach (again, elements in FIG. 5 that are identical to those in previous embodiments retain identical reference numerals). In FIG. 5, output circuit 30″ has an N-channel transistor 46 disposed between middle node 42 and a voltage source V_{PULL-UP}. In this embodiment, V_{PULL-UP} is a constant voltage less than an N-channel threshold voltage (N−Vₜ) below supply voltage V_{dd}. However, V_{PULL-UP} is lower than this, circuit 30″ will tend to draw current in steady state.

With continued reference to FIG. 5, a signal q*, the logical complement to input signal q, is applied to the gate of transistor 46, so that transistor 46 is turned on each time input signal q goes low.

The implementation of FIG. 5 is similar to prior art circuits used (or intended) to pull middle node 42 up during auto-calibration of the constant gate voltage V_{gate} level. Accordingly, such prior art implementations used relatively weak pull-up transistors which were not switched at the data rate, but rather switched on only during auto-calibrate operations.

Another possible way contemplated to counteract the first bit data eye reduction phenomenon is to cause the pre-driver circuit (not shown in the above-referenced Figures) generating input signal q to turn on earlier or turn on faster for the first bit after an extended output time. To determine the pre-driver speed-up, logic can be provided to measure the output off time and then speed up the pre-driver accordingly for the subsequent first bit.

Alternatively, the actual voltage present on middle node 42 can be utilized to determine an appropriate pre-driver speed-up. An example of this is shown in FIG. 6, which shows an output driver circuit 30′″ and an associated pre-driver circuit 48 supplying input signal q thereto.

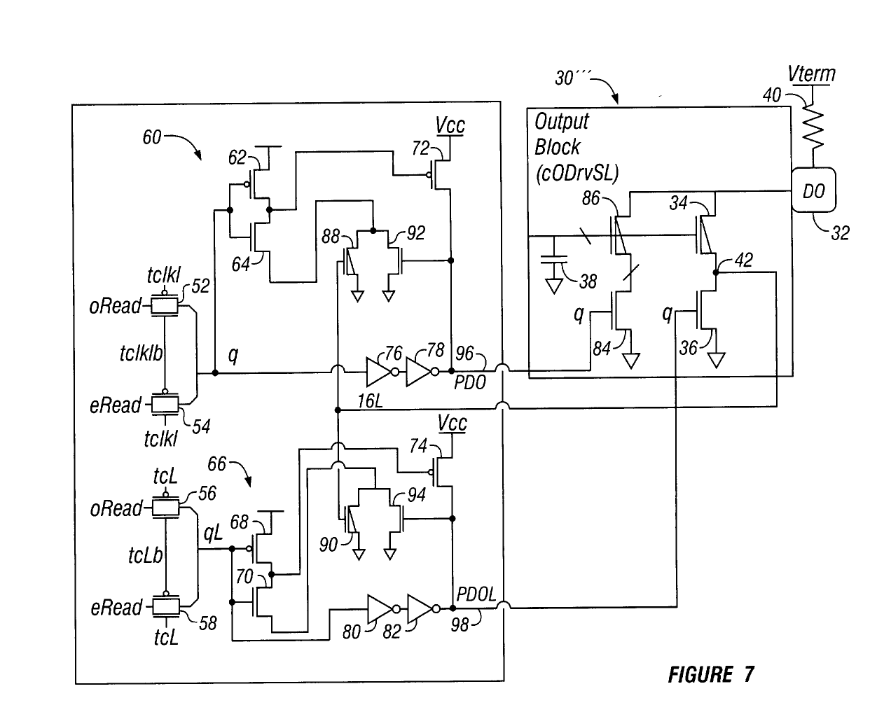

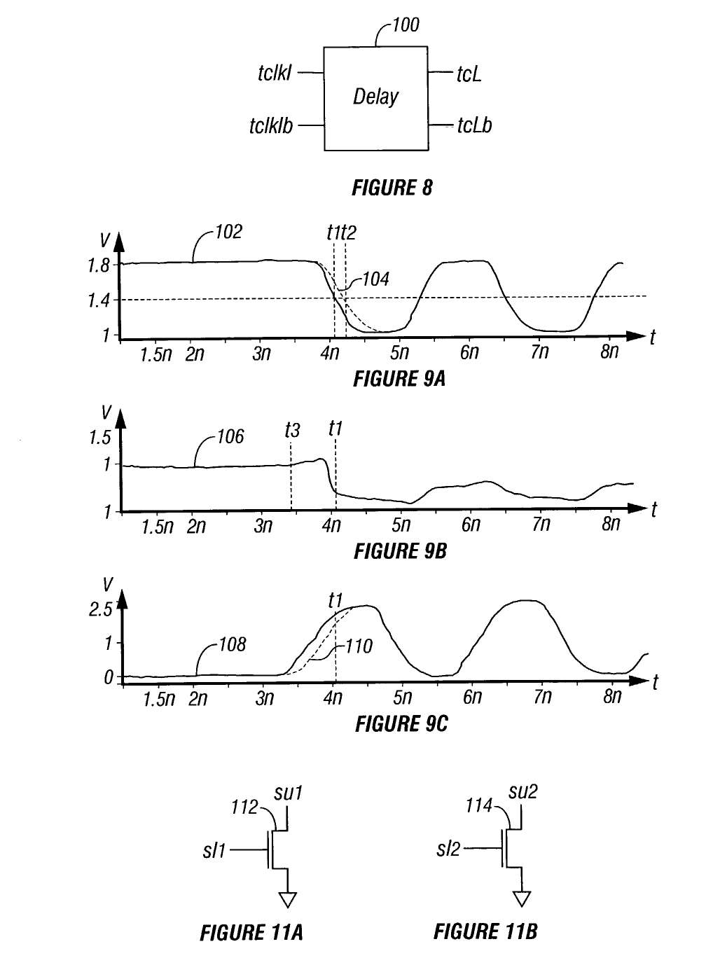

A more detailed schematic depiction of output driver circuit 30′″ and pre-driver circuit 48 is shown in FIG. 7. The inputs to pre-driver circuit comprise signals oRead (odd read data) and eRead (even read data) corresponding to the even and odd read data from a double-data rate memory device. (Although the invention is described with reference to FIG. 7 in the context of a double-data rate memory device, those of ordinary skill in the art having the benefit of the present disclosure will appreciate that the invention is not limited to application in this context, and can be used in essentially any memory device employing an open-drain output circuit.) The eRead and oRead data inputs to pre-driver circuit 48 are applied to two pairs of clocked input passgates 52/54, and 56/58 which are controlled by clock signals tclkl/tclkb and tcL/tcLb, respectively. Clock signal tclkb is the binary complement to clock signal tclkl, while clock signal tcLb is the binary complement to clock signal tcL. In accordance with one aspect of the invention, clock signals tcL/tcLb represent delayed versions of clock signals tclkl/tclkb. As shown in FIG. 8, a delay circuit 100 is provided to generate clock signals tcL/tcLb based on clock signals tclkl/tclklb in accordance with common practice in the art.

As is apparent from FIG. 7, the intermediate pre-driver signal q from passgates 52/54 corresponds to the oRead input signal during one half of each clock cycle and to the eRead input signal during the other half of each clock cycle. Likewise, the intermediate pre-driver signal qL corresponds to the oRead input signal during one half of each clock cycle and the eRead input signal during the other half of each clock cycle. Signal qL tracks signal q, but is slightly delayed relative to signal q owing to the delay in clock signals tcL/tcLb relative to clock signals tclkl/tclklb.

Intermediate pre-driver signal q is applied to the input of an inverter 60 comprising P-channel transistor 62 and N-channel transistor 64. Similarly, intermediate pre-driver signal qL is applied to the input of an inverter 66 comprising P-channel transistor 68 and N-channel transistor 70. The output of inverter 60 is applied to the gate of a P-channel transistor 72, while the output of inverter 66 is applied to the input of P-channel transistor 74

A pair of inverters 76 and 78 buffer and introduce a delay in input signal q, resulting in pre-driver output signal PDO, while a corresponding pair of inverters 80 and 82 buffer and introduce a delay in input signal qL, resulting in pre-driver output signal PDOL. Pre-driver output signal PDO drives the gate of bottom transistor 84 in output circuit 30′″, selectively coupling one terminal of open-drain output transistor 86 to ground. Output transistor 86 receives the regulated V_{gate} signal on its gate, and has its other terminal coupled to output pad 32 as in previous embodiments.

Similarly, pre-driver output signal PDOL is applied to bottom transistor 36 in output circuit 30′″, which selectively couples one terminal of open-drain output transistor 34 to ground. Output transistor 34 receives the regulated V_{gate} signal on its gate and has its other terminal coupled to output pad 32 as in previous embodiments.

With continued reference to FIG. 7, the signal t6L on middle node 42 between output transistors 34 and 36 is fed back to pre-driver circuit 48 and drives the gates of a pair of low-vt N-channel transistors 88 and 90. Transistors 88 and 90 are tailored to achieve the proper pre-driver speed-up, as will be described below in greater detail. When output driver circuit 30′″ has been off for a relatively long time (e.g., on the order of a second), the voltage t6L on middle node 42 will approach 0.9V, thereby biasing transistors 88 and 90 toward turn-on. When intermediate pre-driver signals q and qL go high, transistors 64 and 70 turn on, as do transistors 92 and 94 (following the delay introduced by inverter pairs 76/78 and 80/82, respectively). In this way, transistors 62, 64 and 92 cooperate to selectively turn transistor 72 on and off, by establishing a path between the gate of transistor 72 and ground in response to assertion of intermediate pre-driver signal q. That is, a path from the gate of P-channel transistor 72 to ground is established, through the source-to-drain paths of transistors 64 and 92, thereby turning transistor 72 on, upon assertion of intermediate pre-driver signal q. Likewise, when transistor 94 turns on, a path from the gate of transistor 74 and ground is established, through the source-to-drain paths of transistors 70 and 94, thereby turning transistor 74 on. That is, transistors 70 and 94 cooperate to selectively turn on transistor 74 in response to assertion of intermediate pre-driver signal qL.

The turning on of transistors 72 and 74, in turn, has the effect of pulling up the pre-driver output signals PDO and PDOL on pre-driver output nodes 96 and 98, respectively. Transistors 72 and 74 can thus be considered pull-up transistors with respect to respective nodes PDO and PDOL.

As thus far described, it will be apparent to those of ordinary skill in the art, pre-driver circuit 48 operates to assert pre-driver output signal PDO following a delay interval after assertion of intermediate input signal q. The delay arises due to the propagation of intermediate signal q through inverters 76 and 78 as well as due to the turn-on time of transistor 92. Only when transistor 92 has turned on will transistor 72 turn on, fully pulling PDO output node 96 up to Vcc. Likewise, pre-driver output signal PDOL is asserted following a predetermined delay after assertion of intermediate signal qL, where the delay is due to propagation of signal qL through inverters 80 and 82 and the turn-on time of transistor 94.

In accordance with one aspect of the invention, and as will be appreciated by those of ordinary skill in the art having the benefit of this disclosure, when transistors 88 and 90 are biased toward turn-on due to increased voltage on middle node 42 in output driver circuit 30′″, the pull-up of output nodes 96 and 98 is sped up as compared with the pull-up of those nodes when -transistors 88 and 90 are not biased toward turn-on. That is, pre-driver circuit 48 is responsive to the output circuit 30′″ being off for some period of time (i.e., transistors 36 and 84 being turned off) to reduce the delay between the assertion of signals q/qL and the assertion of signals PDO/PDOL. This is because the biasing of transistors 88 and 90 towards turn-on will effectively reduce the turn-on delay of transistors 92 and 94, respectively. Therefore, when output driver 30′″ has been off for an appreciable period of time, pre-driver 48 will assert pre-driver output signals PDO and PDOL earlier (faster) in response to assertion of read data signals oRead and eRead relative to when it asserts pre-driver signals PDO and PDOL had output driver 30′″ not been off for an appreciable period of time. That is, when output circuit 30′″ has not been off for a sufficient interval that the voltage on middle node 42 increases substantially towards 0.9V, transistors 88 and 90 will not be biased toward turn-on, such that pre-driver circuit 48 will respond to input oRead and eRead signals in a “normal” manner, through the turn-on of transistors and 92 and 94 alone.

It will be apparent to those of ordinary skill in the art that the extent of reduction in the delay between assertion of signals q/qL and the pull-up of nodes PDO/PDOL will vary to some degree with the length of time that output driver 30′″ had been turned off immediately prior to assertion of signals q/qL. The length of time that output driver 30′″ has been turned off will determine the voltage on middle node 42, and hence the extent to which transistors 88 and 90 are biased toward turn-on. This, in turn, determines the extent to which the turn-on delays of transistors 72 and 74 are reduced. The maximum reduction in the delay between assertion of q/qL and assertion of PDO/PDOL will occur when the voltage on middle node has reached its maximum of approximately 0.9V.

FIGS. 9a, 9b, and 9c show plots of various signals present during operation of pre-driver 48 and output driver 30′″ in FIG. 7. In particular, FIG. 9a is a plot of the output voltage V_{PAD} on pad 32 in FIG. 7, FIG. 9b is a plot of the voltage on middle node 42, and FIG. 9c is a plot of the voltage PDO on pre-driver output node 96 in FIG. 7. In FIG. 9a, waveform is the pad voltage V_{pad}. A dashed waveform designated with reference 104 represents the pad voltage without the first-bit compensation implemented in accordance with the present invention. Experimental results show that without first-bit correction, the data eye starts at time t2, roughly 80 picoseconds after time t1, where the data eye starts with first-bit correction in accordance with the presently disclosed embodiment.

FIG. 9b shows the voltage waveform 106 on middle node 42 in output circuit 30′″ in FIG. 7. As shown, waveform 106 hovers at around 0.9V at time t3 after output circuit 30′″ has been off for an extended period of time, e.g., 1 second. FIG. 9c shows the voltage waveform 108 on pre-driver output node 96 in the embodiment of FIG. 7. Dashed waveform 110 indicates the voltage on node 96 without first-bit compensation in accordance with the present invention. From FIG. 9c, is can be plainly observed that, following an extended period with output driver 30′″ being off, the first subsequent assertion of pre-driver output signal PDO occurs sooner following assertion of a read data input to pre-driver 48 than it would occur when driver circuit 30′″ has not been off for an extended time. Stated in an alternative way, the delay between assertion of input data signal and assertion of the pre-driver output signal is shorter for the first bit following an extended off interval for driver circuit 30′″ and for bits not following an extended off interval for driver circuit 30′″.

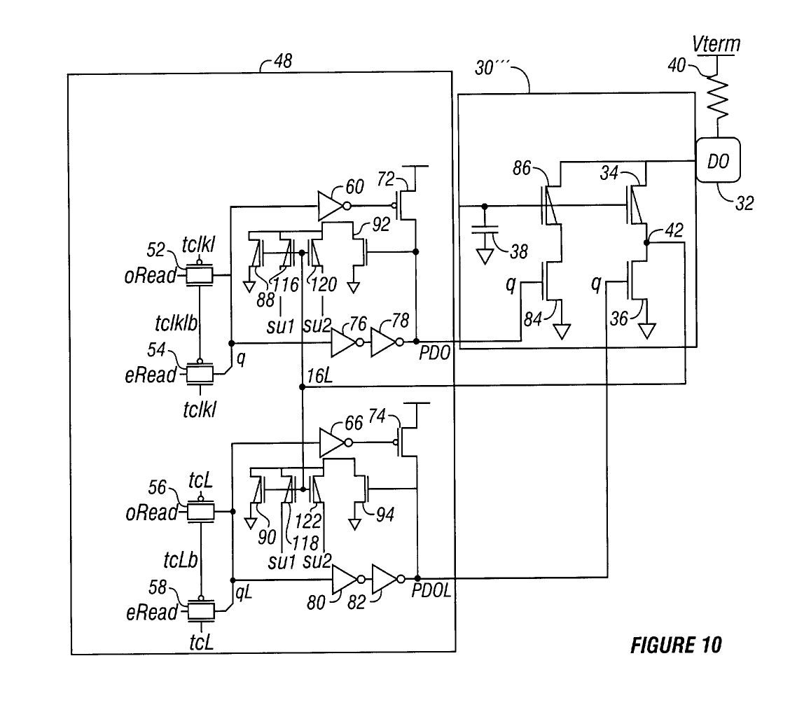

Turning to FIG. 10, there is shown an alternative embodiment of the invention comprising a pre-driver circuit 48′ and output driver circuit 30′″. In the embodiment of FIG. 10, those elements which are substantially identical to those in the embodiment of FIG. 7 have retained identical reference numerals. The embodiment of FIG. 10 allows for fine-tuning of pre-driver circuit 48 from the embodiment of FIG. 7 to take into account such factors as transistor strength, power supply (V_{dd}) voltage levels, and temperature effects. In the embodiment of FIG. 10, a two-bit code <sl1, sl2> is provided to drive the gates of transistors 112 and 114, shown in FIGS. 11a and 11b, respectively, thereby selectively coupling nodes su1 and su2, respectively, to ground. Referring to FIG. 10, node su1 is coupled to one terminal each of N-channel transistors 116 and 118, while node su2 is coupled t0o one terminal each of N-channel transistors 120 and 122. As will be apparent to those of ordinary skill in the art, the logic level of the two-bit code <sl1, sl2> enable various amounts of pre-driver speed-up to be realized such that the optimum first-bit correction can occur under all conditions. Those of ordinary skill in the art will appreciate that an additional number of bits can be added to the compensation code, and additional transistors similar to transistors 116-122, can be implemented to add more degrees of freedom in the control of pre-driver speed-up.

From the foregoing detailed description of specific embodiments of the invention, it should be apparent that methods and apparatuses for correcting anomalous first-bit operation of an open-drain output driver for semiconductor devices has been disclosed. Although specific embodiments of the invention have been disclosed herein in some detail, this has been done solely for the purposes of describing various features and aspects of the invention, and is not intended to be limiting with respect to the scope of the invention. Moreover, it is contemplated that the invention may be practiced in connection with various categories of semiconductor devices having open-drain output circuits, including, without limitation, semiconductor memory devices such as the synchronous DRAM disclosed in U.S. Pat. No. 6,327,196 to Mullarkey, entitled “Synchronous Memory Device Having an Adjustable Data Clocking Circuit,” which patent is commonly assigned to the assignee of the present invention and hereby incorporated by reference herein in its entirety. It is contemplated that various substitutions, alterations, and/or modifications, including but not limited to those implementation variations which may have been suggested herein, may be made to the disclosed embodiments without departing from the spirit and scope of the invention as defined by the appended claims, which follow.

What is claimed is:

1. An open-drain output circuit for a semiconductor device, comprising:
first and second series-connected output transistors coupled between an output pad of said semiconductor device and ground potential, said first and second transistors defining a middle node therebetween, and said first transistor having a gate terminal for receiving a substantially constant voltage applied thereon;
a pre-driver circuit, responsive to assertion of a read data signal applied to an input thereof, to assert a pre-driver output signal following a delay interval beginning upon assertion of said read data signal, said pre-driver output signal being applied to a gate terminal of said second transistor to selectively turn said second transistor on and off;
wherein said output circuit is in an on state when said second transistor is on and is in an off state when said second transistor is off;
wherein said pre-driver circuit is responsive to said output circuit being in said off state for a predetermined period of time to reduce said delay interval upon at least the first subsequent assertion of said read data signal.

2. An open drain output circuit in accordance with claim 1, wherein said pre-driver circuit comprises:
at least one input terminal for receiving a read data signal thereon;
a pre-driver output terminal for presenting said pre-driver output signal thereon;
a pull-up transistor having a first terminal coupled to a positive voltage supply and a second terminal coupled to said pre-driver output terminal; and
a third transistor having a first terminal coupled to a gate of said pull-up transistor, a second terminal coupled to said positive voltage, and a gate terminal coupled to said pre-driver input terminal.

3. An open drain output circuit in accordance with claim 2, wherein said pre-driver circuit further comprises:
a fourth transistor and a fifth transistor, said fourth transistor and said fifth transistor being series connected between said gate of said pull-up transistor and ground potential, said third, fourth and fifth transistors being cooperatively responsive to assertion of said read data signal to turn on said pull-up transistor.

4. An open drain output circuit in accordance with claim 3, wherein said pre-driver circuit further comprises:
a sixth transistor, coupled in parallel with said fourth transistor between said fifth transistor and ground potential, said sixth transistor having a gate terminal coupled to said middle node.

5. An open drain output circuit in accordance with claim 4, wherein when said second transistor is turned off, voltage on said middle node begins to rise from approximately ground potential and reaches a maximum of approximately 0.9 volts.

6. An open drain output circuit in accordance with claim 5, wherein said voltage on said middle node rising toward approximately 0.9 volts biases said sixth transistor towards an on state.

7. An open drain output circuit in accordance with claim 6, wherein said sixth transistor being biased toward said on state speeds up the turning on of said pull-up transistor in response to assertion of said read data input signal, such that the length of said delay interval for any given assertion of said read data input signal varies depending upon the length of time that said second transistor has been turned off prior to such given assertion.

8. A semiconductor memory device, comprising:
an open drain output circuit coupled to an output terminal of said memory device, said open drain output circuit being responsive to assertion of a pre-driver output signal to turn on, thereby driving a logical low signal on said output terminal, and being responsive to deassertion of said pre-driver output signal to turn off, thereby driving a logical high signal on said output terminal;
a pre-driver circuit having an output coupled to said open drain output circuit and responsive to assertion of a read data input signal to assert said pre-driver output signal following a delay interval;
wherein said delay interval is shorter whenever said open drain output circuit has been off for more than a predetermined period of time relative to when said open drain output circuit has not been off for more than said predetermined period of time.

9. A semiconductor memory device in accordance with claim 8, wherein said predetermined period of time is less than one second.

10. A semiconductor memory device in accordance with claim 8, wherein said pre-driver circuit comprises a pull-up transistor coupled between a positive voltage source and said pre-driver circuit output.

11. A semiconductor memory device in accordance with claim 10, wherein said pre-driver circuit comprises delay circuitry, coupled to said pull-up transistor, and responsive to assertion of said read data signal, to turn on said pull-up transistor.

12. A semiconductor memory device in accordance with claim 11, wherein said delay circuitry is coupled to said middle node in said open drain output circuit and is responsive to a voltage on said middle node to shorten said delay.

13. A semiconductor memory device in accordance with claim 12, wherein said voltage on said middle node gradually begins to rise from approximately ground potential when said open drain output circuit is turned off.

14. A method of operating an output circuit for a semiconductor device having a data output terminal, comprising:
(a) each time a read data input signal within said device is asserted, turning on an open drain output driver after a delay following such assertion;
(b) each time said read data input signal is deasserted, turning off said open drain output driver after a delay following such deassertion;
(c) shortening said delay following assertion of said read data input signal by an increment determined by the length of time immediately prior to said assertion of said read data input signal that the open drain output driver has been turned off.

15. A method in accordance with claim 14, further comprising:
(d) monitoring a voltage on a middle node in said open drain output driver, where said voltage is known to rise above ground potential towards 0.9V whenever said open drain output circuit remains off, reaching a voltage of approximately 0.9V when said open drain output circuit remains off for said at least a predetermined period of time;
wherein said increment is at a maximum when said voltage reaches approximately 0.9V.
